(19) United States
(12) Patent Application Publication
(10) Pub. No.: US 2026/0150329 A1
(43) Pub. Date: May 28, 2026

(54) SEMICONDUCTOR DEVICE AND METHOD OF MAKING THE SAME

(71) Applicant: EPISIL TECHNOLOGIES INC., Hsinchu County (TW)

(72) Inventors: Yuan-Liang LIU, Hsinchu County (TW); Yi-Chen LEE, Hsinchu County (TW); Yuan-Chou CHANG, Hsinchu County (TW); Yen-Chang CHEN, Hsinchu County (TW)

(21) Appl. No.: 19/173,321

(22) Filed: Apr. 8, 2025

(30) Foreign Application Priority Data
Nov. 26, 2024 (TW) 113145535

(51) Int. Cl. H10D 30/63; H01L 21/04; H10D 30/01; H10D 62/10; H10D 62/60; H10D 62/832

(52) U.S. Cl. CPC H10D 30/63; H10D 30/025; H10D 62/124; H10D 62/60; H10D 62/8325; H10P 30/22

(57) ABSTRACT

A semiconductor device includes a silicon carbide (SiC) epitaxial substrate, two well regions, a junction field-effect transistor region, two source regions, two lightly doped regions, two heavily doped regions, a gate terminal, and a drain terminal. The well regions are spaced apart, extend downward from a top surface of the SiC epitaxial substrate, and doped with a second type dopant. The junction field-effect transistor region extends downward between the well regions without contacting the well regions and doped with a first type dopant. The source regions are located in the two well regions. The two lightly doped region are respectively juxtaposed to the source regions and each has a first lightly doped layer, and a second lightly doped layer. The heavily doped regions are below the source regions. The gate terminal is located between the two source regions. A method for making the semiconductor device is also included.

### CROSS-REFERENCE TO RELATED APPLICATION

This application claims priority to Taiwanese Invention Patent Application No. 113145535, filed on Nov. 26, 2024, the entire disclosure of which is incorporated by reference herein.

### FIELD

The disclosure relates to a semiconductor device, and more particularly to a semiconductor device and a method for making the same.

### BACKGROUND

Silicon carbine (SiC) has many advantages such as high pressure and high temperature tolerance, and is currently widely used in electronic components where characteristics such as high temperature and pressure tolerance are required.

Conventionally, in order to lower the drain-source on-resistance (Rdson) of an SiC planar metal oxide semiconductor field effect transistor (MOSFET) so that its power consumption may be decreased, the cell pitch of the SiC planar MOSFET would need to be reduced. However, when reducing the cell pitch, various technical bottlenecks may be encountered (such as misalignment, or restrictions in the metal filling capacity of the source contact pad), and electrical characteristics of the SiC planar MOSFET may be affected, thereby deviating from standard electrical characteristics.

More specifically, the cell pitch of the SiC planar MOSFET may be reduced via reducing the width of the junction field-effect transistor (JFET) region. However, in doing so, the channel length will also be shortened, and a short channel effect may cause unstable threshold voltage (Vth) and higher electric field in the channel which may induce hot carrier injection. This may affect the reliability of the SiC planar MOSFET. Furthermore, by reducing the width of the JFET region, the electrical resistance of the JFET region will increase which will consequently increase the Rdson. In order to avoid reducing the width of the JFET region of the SiC planar MOSFET which may cause raised RJEFT in the in the SiC planar MOSFET, the JFET region is doped (JF implant) with a higher doping concentration (more heavily doped) to counteract the increase in the resistance of the JFET region. However, bottlenecks in current processing technology means that when the conventional semiconductor device is fabricated the JFET region will partially overlap with the well regions, and the heavily doped JFET region will lower the doping concentration of the well region which will reduce the threshold voltage (Vth) of the semiconductor device. When the threshold voltage (Vth) is too low, the conventional semiconductor device may be easily affected by signal noise.

### SUMMARY

Therefore, an object of the disclosure is to provide a semiconductor device and a method of making the semiconductor device that can alleviate at least one of the drawbacks of the prior art.

According to a first aspect of the disclosure, the semiconductor device includes a silicon carbide (SiC) epitaxial substrate, two well regions, a junction field-effect transistor region, two source regions, two lightly doped regions, two heavily doped regions, a gate terminal, and a drain terminal. The SiC epitaxial substrate has a top surface and a bottom surface that is opposite to the top surface. The two well regions are spaced apart from each other, each extending downward from the top surface of the SiC epitaxial substrate, and each being doped with a second type dopant. The junction field-effect transistor region extends downward from the top surface of the SiC epitaxial substrate, is located between the two well regions, and is doped with a first type dopant. The two source regions are respectively extending downward from the top surface of the SiC epitaxial substrate and located in the two well regions. The two lightly doped regions are respectively disposed in the well regions, and each has a first lightly doped layer extending downward from the top surface of the SiC epitaxial substrate, and juxtaposed to an upper part of a boundary edge of a corresponding one of the source regions, and a second lightly doped layer that extends downward from the first lightly doped layer to be juxtaposed to a lower part of the boundary edge of the corresponding one of the source regions, and that extends downward further to underlie the corresponding one of the source regions. The first lightly doped layer is doped with a first type dopant. The second lightly doped layer is doped with a second type dopant, and has a width that is greater than a width of the first lightly doped layer. The two heavily doped regions are each formed below a corresponding one of the source regions, without extending beyond a bottom surface of a corresponding one of the well regions. The gate terminal is located on the top surface of the SiC epitaxial substrate between the two source regions. The gate terminal has two opposite lateral end portions that respectively overlap the source regions. The drain terminal is located on the bottom surface of the SiC epitaxial substrate.

According to a second aspect of the disclosure, the semiconductor device includes a SiC epitaxial substrate, two well regions, a junction field-effect transistor region, and two source regions. The SiC epitaxial substrate has a top surface and a bottom surface that is opposite to the top surface. The two well regions are spaced apart from each other, each extending downward from the top surface of the SiC epitaxial substrate, and each is doped with a second type dopant. The junction field-effect transistor region extends downward from the top surface of the SiC epitaxial substrate, is located between the two well regions, and is doped with a first type dopant. The junction field-effect transistor region has a lateral width smaller than a distance between the two well regions so that the junction field-effect transistor region does not contact the two well regions. The two source regions respectively extend downward from the top surface of the SiC epitaxial substrate, and are located in the two well regions. A gate terminal is located on the top surface of the SiC epitaxial substrate between the two source regions. The gate terminal has two opposite lateral end portions that respectively overlap the source regions. A drain terminal is located on the bottom surface of the SiC epitaxial substrate.

According to still another aspect of the disclosure, a method for making the semiconductor device includes: A) forming a first hard mask unit on a top surface of a silicon carbide (SiC) epitaxial substrate, the first hard mask unit having a first hard mask layer, a second hard mask layer, and a third hard mask layer that are sequentially stacked upwardly from the top surface of the SiC epitaxial substrate; B) etching the first hard mask unit via a photolithography process form the third hard mask layer to the first hard mask layer to form at least two first openings that are spaced apart from each other; C) doping the SiC epitaxial substrate via ion implantation through the first openings to respectively form a plurality of well regions that are doped with a second type dopant, and that are spaced apart from each other; D) forming a first mask film over the hard mask unit which is etched to cover the third mask layer and the first openings, and then removing the first mask film from the third hard mask layer and a portion of each of the first openings, residual thickness portions of the first mask film being left on boundaries of the first openings to respectively form second openings that each has a size smaller than a size of each of the first openings; E) performing a first ion implantation through each of the second openings to form a first lightly doped layer, and then performing a second ion implantation through each of the second openings to form a second lightly doped layer that is below the first lightly doped layer and that has a width greater than a width of the first lightly doped layer, the first lightly doped layer being doped with a first type dopant, the second lightly doped layer being doped with a second type dopant; F) forming a fourth hard mask layer covering the third hard mask layer, the first mask film, and the first hard mask layer exposed from the second openings, forming a second mask film covering the fourth hard mask layer, and then removing the portions of the second mask film corresponding in position to the third hard mask layer and the second openings, residual thickness portions of the second mask film being left on boundaries of the second openings to respectively form third openings that each has a diameter that is smaller than a diameter of each of the second openings; G) performing an ion implantation through the third openings to respectively form a plurality of source regions that are doped with a first type dopant, that have a doping concentration greater than doping concentrations of the first and second lightly doped layers and that each extends downwardly from the top surface past the first lightly doped layer into the second lightly doped layer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a first embodiment of a semiconductor device of the present disclosure.

FIG. 2 is a schematic cross-sectional flow diagram illustrating steps A) to C) of second embodiment which is a method for making a semiconductor device.

FIG. 3 is a schematic cross-sectional flow diagram illustrating steps D) to E) of the second embodiment.

FIG. 4 is a schematic cross-sectional flow diagram illustrating steps F) to G) of the second embodiment.

FIG. 5 is a schematic cross-sectional flow diagram illustrating steps H) to I) of the second embodiment.

FIG. 6 is a schematic cross-sectional flow diagram illustrating steps J) to K) of the second embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

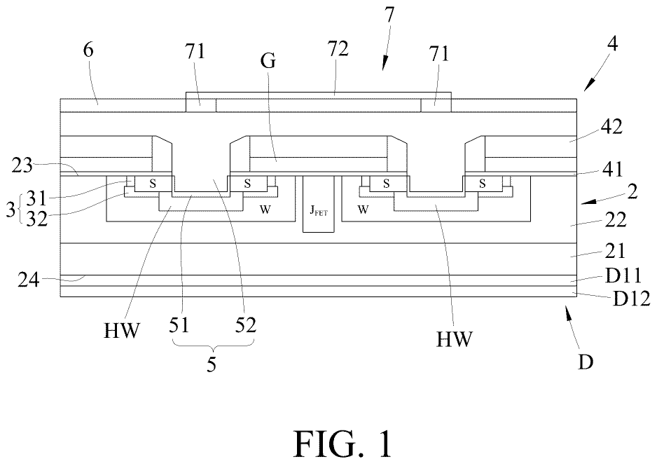

Referring to FIG. 1, a first embodiment of a semiconductor device according to the present disclosure includes a silicon carbide (SiC) epitaxial substrate 2, two well regions (W), a junction field-effect transistor region (J_{fet}), two source regions (S), two lightly doped regions 3, two heavily doped regions (HW), a gate terminal (G), a drain terminal (D), an insulating layer 4, a conducting unit 5, a protection unit 6, and an electrical connection unit 7.

The SiC epitaxial substrate 2 is doped with a first type dopant, has an SiC substrate material 21, a SiC epitaxial film 22, a top surface 23, and a bottom surface 24 that is opposite to the top surface 24. It should be noted that the first type dopant used to dope the SiC epitaxial substrate 2 has a first type conductivity, and a second type dopant will have a second type conductivity that is opposite to the first type conductivity. For example, the first type dopant may be an N-type dopant, and the second type dopant may be a P-type dopant. In other examples, the first type dopant may be a P-type dopant, and the second type dopant may be the N-type dopant. In this embodiment, the semiconductor device is a planar metal oxide semiconductor (MOS), the first type dopant is an N-type dopant, the N-type dopant may be nitrogen (N) or phosphorus (P), and the P-type dopant may be aluminum (Al).

The two well regions (W) are spaced apart from each other, are each extending downwardly from the top surface 23 of the SiC epitaxial substrate 2, and are located in the SiC epitaxial film 22. In this embodiment, the two well regions (W) are each doped with a second type dopant (a P-type dopant).

The junction field-effect transistor region (J_{fet}) extends downward from the top surface 23 of the SiC epitaxial substrate 2, and is located between the two well regions (W). In this embodiment, the junction field-effect transistor region (J_{fet}) is located between the two well regions (W) without contact with the two well regions (W). The junction field-effect transistor region (J_{fet}) has a lateral width smaller than a distance between the two well regions (W) so that the junction field-effect transistor region (J_{fet}) does not contact the two well regions (W). In this embodiment, the junction field-effect transistor region (J_{fet}) is doped with a first type dopant (an N-type dopant).

The two source regions (S) are respectively extending downward from the top surface 23 of the SiC epitaxial substrate 2 and are respectively located in the two well regions (W).

The two lightly doped regions 3 are respectively disposed in the well regions (W), and each have a first lightly doped layer 31 extending downward from the top surface 23 of the SiC epitaxial substrate 2 and juxtaposed to an upper part of a boundary edge of a corresponding one of the source regions (S), and a second lightly dope layer 32 that extends downward from the first lightly doped layer 31 and is juxtaposed to a lower part of the boundary edge of the corresponding one of the source regions (S), and that extends downward further to underlie the corresponding one of the source regions (S). Each source region (S) has a bottom end at a depth that is between the depth of a bottom end of the first lightly doped layer 31 and the depth of a bottom end of the second lightly doped layer 32.

In this embodiment, the first lightly doped layer 31 is doped with a first type dopant (an N-type dopant), and the second lightly doped layer 32 is doped with a second type dopant (a P-type dopant). The second lightly doped layer 32 has a width that is greater than a width of the first lightly doped layer 31. More specifically, a width between an edge of the first lightly doped layer 31 and an edge of the respective source region (S) is defined as the channel. The second lightly dope layer 32 is located below the first lightly doped layer 31 and a horizontal distance from an edge of the second lightly dope layer 32 to the edge of the respective well region (W) is less than the horizontal distance of that of the first lightly doped layer 31. Therefore, the edge of the second lightly doped layer 32 of each lightly doped region 3 is closer to the edge of the respective well region (W) than the edge of the first lightly doped layer 31 of the lightly doped region 3, and the second lightly doped layer 32 has a width that is greater than the width of the first lightly dope layer 31. The second lightly doped layer 32 has a doping concentration that is less than a doping concentration of the well regions (W).

The two heavily doped regions (HW) are each formed below a corresponding one of the source regions (S) without extending beyond a bottom surface of a corresponding one of the well regions (W). The second lightly doped layer 32 of each of the lightly doped regions 3 extends downward from a bottom of the corresponding one of the source regions (S) and is juxtaposed to a boundary wall of the heavily doped region (HW). The two heavily doped regions (HW) is doped with a dopant that is of the same type as the well regions (W). Additionally, the heavily doped regions (HW) has a doping concentration that is higher than the doping concentration of the well regions (W).

The gate terminal (G) is located on the top surface (23) of the SiC epitaxial substrate 2 between the two source regions (S). The gate terminal (G) has two opposite lateral end portions that respectively overlap the source regions (S).

The insulating layer has a first insulating layer 41, that is made of an oxide material, and that covers the top surface 23 of the SiC epitaxial substrate 2, and a second insulating layer 42 that is located above the first insulating layer 41, that is made of a dielectric insulating material, and that covers the gate terminal (G). The gate terminal (G) is located above the first insulating layer 41.

The conducting unit 5 has an ohmic contact layer 51 that is electrically connected to the source regions (S), and a source electrode 52 that is electrically connected to the ohmic contact layer 51.

The protection unit 6 is made of an insulating material, is located above the second insulating layer 42, and covering the source electrode 52.

The connecting unit 7 has a plurality of conducting structures 71 that passes through the protection unit 6 to electrically connect the gate terminal (G) and the source electrode 52, and an electrical conductor 72 for external electrical connection. The electrical conductor 72 is electrically connected to the conducting structures 71, is located above the protection unit 6, and electrically connects the source region (S) and the gate terminal (G) to an external electrical connection via 3D wiring (the drawings only show the conducting structures 71 connected to the source region (S) and the electrical conductor 72).

The ohmic contact layer 51 of the conducting unit 5 may be made of a metal silicide such as nickel silicide (Ni silicide). The source electrode 52 may be a metal or an alloy such as titanium (Ti), titanium nitride (TiN), or aluminum copper alloy (AlCu). The protection unit 6 may be made of an insulating material such as an oxide or a nitride and may be a single layered structure or a multi-layered structure. The electrical conductor 72 may be made of a metal or alloy such as titanium (Ti), titanium nitride (TiN), or aluminum copper alloy (AlCu), and may be a single layered or multi-layered structure.

The drain terminal (D) is located on the bottom surface 24 of the SiC epitaxial substrate 2. The drain terminal (D) includes a metal silicon layer (D11) formed on the bottom surface 24 of the SiC epitaxial substrate 2, and a metallic conducting layer (D12) formed on the metal silicon layer (D11). The metallic conducting layer (D12) may be made from the same materials used for the source electrode 52 and the electrical conductor 72. The metal silicon layer (D11) may be made of the same materials used for the ohmic contact layer 51.

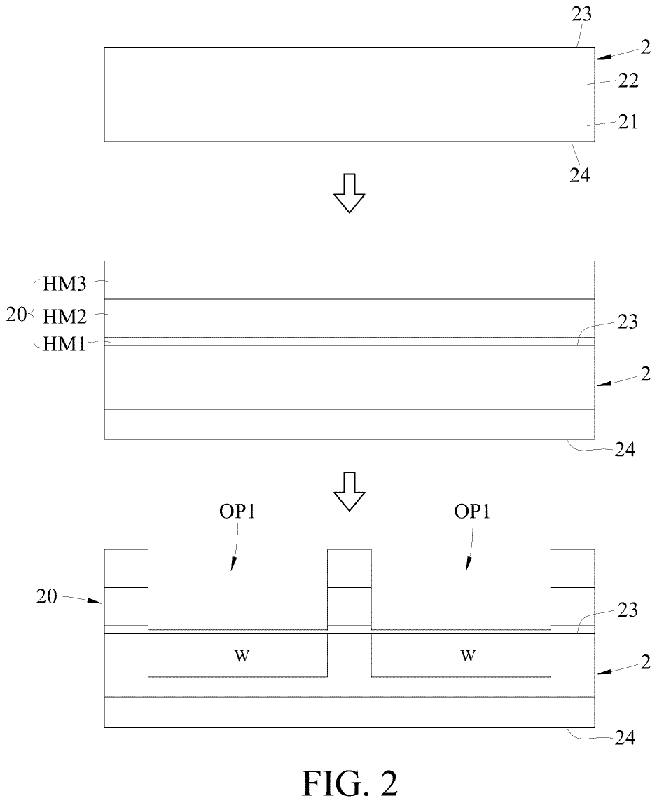

In a second embodiment of the disclosure, a method for making a semiconductor device is provided, which includes the steps A) to L). Referring to FIGS. 1 and 2, in the step A), an SiC epitaxial substrate 2 is prepared, and a first hard mask unit 20 is formed on a top surface 23 (which may be the surface of the SiC epitaxial film 22 in the first embodiment) of the SiC epitaxial substrate 2. The first hard mask unit 20 has a first hard mask layer (HM1), a second hard mask layer (HM2), and a third hard mask layer (HM3) that are sequentially stacked upwardly from the top surface 23 of the SiC epitaxial substrate 2. More specifically, the first hard mask unit 20 may be formed by sequentially performing chemical vapor deposition (CVD) to form the first hard mask layer (HM1), the second hard mask layer (HM2), and the third hard mask layer (HM3). The first hard mask unit 20 may be made of a nitride, an oxide, or a polycrystalline silicon. Additionally, the first hard mask layer (HM1), the second hard mask layer (HM2), and the third hard mask layer (HM3) has high etch selectivity to facilitate the formation of an etch stop layer.

Next, in the step B, a photoresist is formed on the third hard mask layer (HM3), the photoresist is exposed to form a plurality of spaced apart openings, and the hard mask unit 20 is etched through the openings via a photolithography process from the third hard mask layer (HM3) to the first hard mask layer (HM1) to form at least two first openings (OP1) that are spaced apart from each other. The photoresist is then removed.

Afterwards, in the step C) the SiC epitaxial substrate 2 is doped via ion implantation through the first openings (OP1) to respectively form at least two well regions (W) in the SiC epitaxial film 22 that are doped with a second type dopant, and that are spaced apart form each other. In this embodiment, the second type dopant is a P-type dopant.

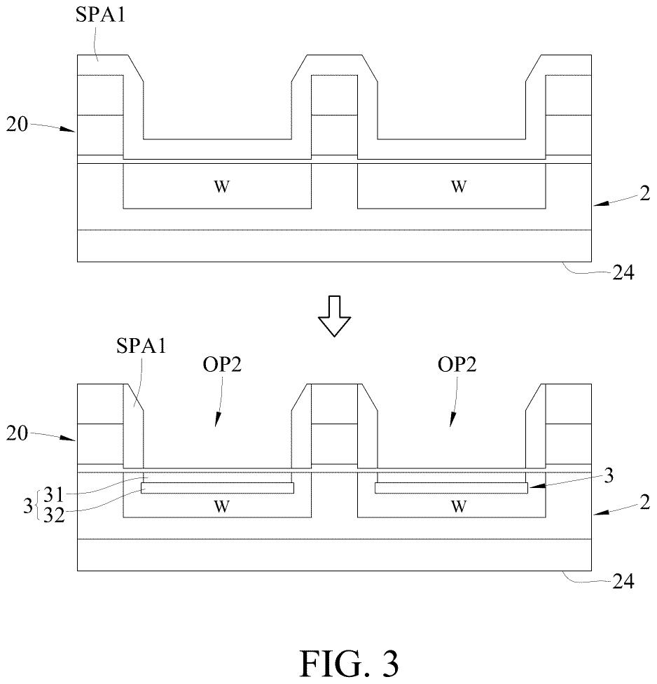

Referring to FIG. 3, in the step D), after performing the step C), a first mask film (SPA1) is formed over the hard mask unit 20, which is etched, to cover the third hard mask layer (HM1) and the first openings (OP1). The first mask film (SPA1) may be made of an oxide material or a nitride material. Additionally, it should be noted that the first hard mask layer (HM1) and the third hard mask layer (HM3) has a higher etching selectivity compared to the first mask film (SPA1). Next, the first mask film (SPA1) is removed from the third mask layer (HM3) and each of the first openings (OP1) via an etching back process. Residual thickness portions of the first mask film (SPA1) are left on boundaries of the first openings (OP1) to respectively form second openings (OP2) that each has a size smaller than a size of each of the first openings (OP1).

Next, in the step E) a first ion implantation is performed through each of the second openings (OP2) to form a first lightly doped layer 31, and then a second ion implantation is performed through each of the second openings (OP2) to form a second lightly doped layer 32 that is located below the first lightly doped layer 31 and that has a width that is greater than a width of the first lightly doped layer 31. The first lightly doped layer 31 is doped with a first type dopant; the second lightly doped layer 32 is doped with a second type dopant. In this embodiment, the first lightly doped layer 31 is doped with an N-type dopant, and the second lightly doped layer 32 is doped with a P-type dopant. Furthermore, when performing the second ion implantation, the ion implantation may be controlled to implant ions at an angle. Additionally, in some embodiments, when performing the first ion implantation, the implantation may also be controlled to implant ions at an angle according to requirements so long as the width of the second lightly doped layer 32 is greater than the width of the first lightly doped layer 31.

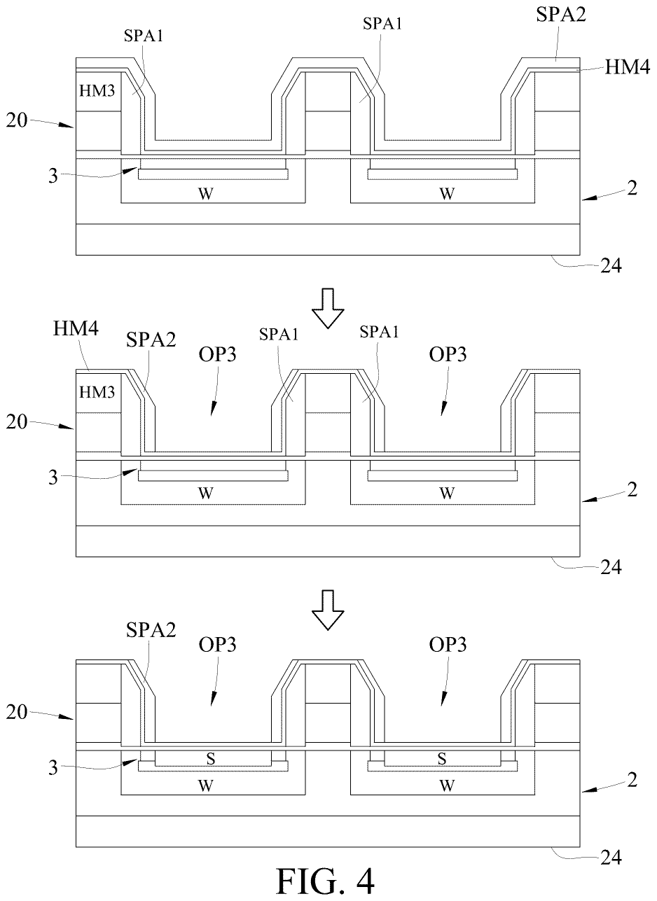

Referring to FIG. 4, next, in step F) a fourth hard mask layer (HM4) covering the third hard mask layer (HM3), the first mask film (SPA1), and the first hard mask layer (HM1) exposed from the second openings (OP2) is formed via deposition. A second mask film (SPA2) covering the fourth hard mask layer (HM4) is also formed. It is noted that the second mask film (SPA2) may be made of an oxide material or a nitride material, and the fourth hard mask layer (HM4) has high etch selectivity. Afterwards, the portions of the second mask film (SPA2) corresponding in position to the third hard mask layer (HM3) and the second openings (OP2) is removed via an etching back process. Residual thickness portions of the second mask film (SPA2) are left on boundaries of the second openings (OP2) to respectively form third openings (OP3) that each has a diameter that is smaller than a diameter of each of the second openings (OP2).

Afterwards, in a step G), an ion implantation is performed through the third openings (OP3) to respectively form a plurality of source regions (S) that are doped with a first type dopant, that have a doping concentration that is greater than doping concentrations of the first and second lightly doped layers 31, 32, and that each extends downwardly from the top surface 23 of the SiC epitaxial substrate 2. Each source region (S) has a bottom end at a depth that is located between the depth of the bottom end of the first lightly doped layer 31 and the depth of the bottom end of the second lightly doped layer 32. In this embodiment, the source regions (S) are doped with an N-type dopant.

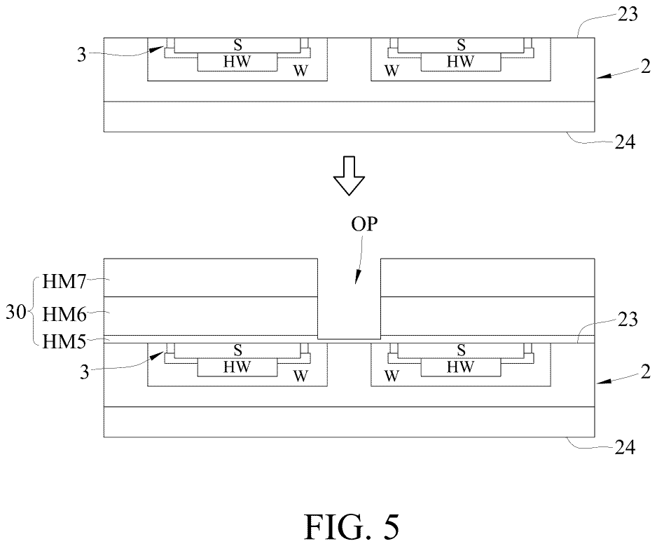

Referring to FIG. 5, in the step H), an acid (such as HF) is used to remove the first to fourth hard mask layers (HM1, HM2, HM3, HM4) and the first and second mask films (SPA1, SPA2). A photoresist layer (not shown) is formed on the top surface 23 of the SiC epitaxial substrate 2 which is then patterned to form a patterned photoresist layer via photolithography. The patterned photoresist layer defines at least two doping openings (not shown) that have a width smaller than that of the source regions (S). And then, a heavily doped ion implantation is performed through the doping openings to respectively form heavily doped regions (HW) that are doped with a second type dopant. Afterwards, the patterned photoresist layer is removed.

Next, in the step I), a second hard mask unit 30 having a fifth hard mask layer (HM5), a sixth hard mask layer (HM6), and a seventh hard mask layer (HM7) that are sequentially stacked upwardly from the top surface 23 of the SiC epitaxial substrate 2 is formed. And then, a photoresist (not shown) is formed on the second hard mask unit 30 that is patterned via photolithography to form patterned photoresist having a photoresist opening that is located between the two well regions (W). Afterward, through the photoresist opening, the seventh hard mask layer (HM7), the sixth hard mask layer (HM6) and the fifth hard mask layer (HM5) are etched until reaching a depth in the fifth hard mask layer (HM5), thereby forming an opening (OP) between the two well regions (W). Afterwards, the patterned photoresist is removed.

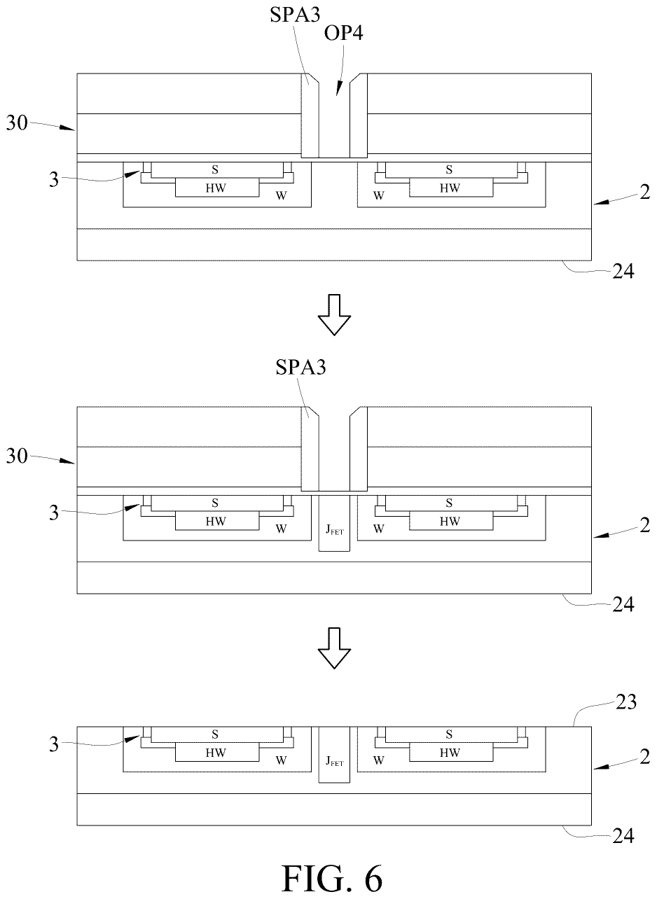

Referring to FIG. 6, in the step J), after performing the step I), a third mask film (SPA3) is formed via CVD to cover the second hard mask unit 30. It should be noted that the third mask film (SPA3) may be made of an oxide material or a nitride material, and the fifth hard mask layer (HM5) and the seventh hard mask layer (HM7) has higher etch selectivity compared to the third mask film (SPA3). Next, the portion of the third mask film (SPA3) corresponding in position to the seventh hard mask layer (HM7) and the opening (OP) is removed via an etching back process. A residual thickness portion of the third mask film (SPA3) is left in the opening (OP) to form a fourth opening (OP4) that has a width that is smaller than a minimum distance between the well regions (W).

Next, in the step K), an ion implantation is performed through the fourth opening (OP4) to form a junction field-effect transistor region (J_{fet}) that is doped with a first type dopant, that is located between the well regions (W) without contacting the well regions (W). Afterwards, the residual portion of the third mask film (SPA3) and the second hard mask unit 30 are removed to expose the top surface 23 of the SiC epitaxial structure 2.

Afterwards, referring to FIGS. 1 and 6, in the step L) an insulating layer 4 is formed. The insulating layer 4 has a first insulating layer 41 that covers the top surface 23 of the SiC epitaxial substrate 2, a polycrystalline silicon layer (not shown) formed on the first insulating layer 41, and a second insulating layer 42 that is located above the first insulating layer (41). The first and second insulating layers 41, 42 (as shown in FIG. 1) may be made of an oxide material or a nitride material. When they are made of an oxide material, they may be formed via thermal oxidation or deposition. When they are made of a nitride material, they may be formed via CVD. Because oxide and nitride materials and their methods of formation are well known in the art, further details are omitted for the sake of brevity.

Next, the gate terminal (G) is formed to be located above the first insulating layer 41 and is covered by the second insulating layer 42.

Next, a conducting unit 5 connected to the source regions (S) is formed. The conducting unit 5 has an ohmic contact layer 51 formed on the heavily doped regions (HW) and a source electrode 52 formed on the ohmic contact layer 51 via deposition. The ohmic contact layer 51 and the source electrode 52 may be formed with a crystalline silicon material.

A conducting structure 7 is formed to pass through the protection unit 6 to electrically connect with the gate terminal (G) and the source regions (S), and an electrical conductor 72 is formed for external electrical connection. FIG. 1 only shows the conducting structures 71 connected to the source region (S) and the electrical conductor 72. Finally, a drain terminal (D) is formed at a bottom surface (24) of the SiC epitaxial substrate 2.

Because miniaturization of semiconductor devices by shrinking dimensions of semiconductor devices, such as transistors, will reduce the length of transistor channels, the semiconductor device according to the present disclosure is provided with the first lightly dope layer 31 that is doped with the first type dopant and that is disposed at a side of the respective source region (S) near the channel, and the second lightly doped layer 32 that is located below the first lightly doped layer 31. The second lightly doped layer 32 has a lateral width that is extended laterally toward the boundary of the respective well region (W) to become longer than a lateral width of the first lightly doped layer 31. This mitigates the negative effects of the reduced channel length. The first lightly doped layer 31 and the second lightly doped layer 32 help the semiconductor device to suppress the short-channel effect and reduce hot-carrier injection.

Additionally, shrinking transistor dimensions will also reduce the distance between well regions. However, conventional photolithography cannot accurately etch narrow openings. Therefore, when the semiconductor device is shrunk for miniaturization, the opening on the mask used in the prior art to dope and form the junction field-effect transistor region may overlap with the well region below and cause the thus formed junction field-effect transistor region to contact the well region. Conventionally, when the size of the semiconductor device is miniaturized, the doping concentration of the junction field-effect transistor region is increased in order to decrease drain-source on-resistance (Rdson). And when the junction field-effect transistor region contacts the well region due to miniaturization, the electrical characteristics of the well region will be negatively affected by the highly doped junction field-effect transistor region and cause the threshold voltage (Vth) to be reduced which may lead to failure in the semiconductor device.

Therefore, in the steps I), J) and K) of the method of the present disclosure, the opening (OP) (see FIG. 5) with a bigger aperture is first formed using a conventional photolithography process, and the third mask film (SPA3) is etched via an etch back process to leave a residual thickness portion on the boundary of the opening (OP) to define a smaller fourth opening (OP4) (see FIG. 5). The thickness of the third mask film (SPA3) and parameters of the etch back process are carefully controlled to precisely control the residual thickness portion of the third mask film (SPA3) in order to form the fourth opening (OP4) that has a more narrow profile (a higher depth to width ratio). In this way, the small aperture fourth opening (OP4) with high precision is formed, and the junction field-effect transistor region (J_{fet}) that is formed through the fourth opening (OP4) may be precisely controlled to avoid contact with the adjacent well regions (W). Thus, the junction field-effect transistor regions (J_{fet}) of the present disclosure may be highly doped to decrease Rdson without effecting threshold voltage (Vth) of the semiconductor device, and allow the semiconductor device to function normally.

In summary of the above, in the semiconductor device according the present disclosure, by carefully controlling the fabrication process to form the first lightly doped layer 31 doped with the first type dopant via ion implantation through the second openings (OP2), and then forming the second lightly doped layer 32 that has a width that is greater than a width of the first lightly doped layer 31 and doped with the second type dopant, hot carrier injection may be suppressed, and short channel effect due to miniaturization of the semiconductor device may be avoided. Additionally, by controlling the fabrication process so that the junction field-effect transistor region (J_{fet}) does not contact any one of the well regions (W), the negative effects on electrical characteristics due to a heavily doped junction field-effect transistor region may be alleviated. In this way the semiconductor device according to the present disclosure may function without failure and the object of the disclosure may be accomplished.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor device comprising:
a silicon carbide (SiC) epitaxial substrate having a top surface and a bottom surface that is opposite to said top surface;
two well regions spaced apart from each other, each extending downward from said top surface of said SiC epitaxial substrate, and each being doped with a second type dopant;
a junction field-effect transistor region (J_{fet}) extending downward from said top surface of said SiC epitaxial substrate, located between said two well regions, and doped with a first type dopant;
two source regions extending downward from said top surface of said SiC epitaxial substrate and respectively located in said two well regions;
two lightly doped regions respectively disposed in said well regions, and each having a first lightly doped layer extending downward from said top surface of said SiC epitaxial substrate to be juxtaposed to an upper part of a boundary edge of a corresponding one of said source regions, and a second lightly doped layer that extends downward from said first lightly doped layer to be juxtaposed to a lower part of said boundary edge of said corresponding one of said source regions, and that extends downward further to underlie said corresponding one of said source regions, said first lightly doped layer being doped with said first type dopant, said second lightly doped layer being doped with said second type dopant, and having a width that is greater than a width of said first lightly doped layer;
two heavily doped regions each formed below a corresponding one of said source regions, without extending beyond a bottom surface of a corresponding one of said well regions;
a gate terminal located on said top surface of said SiC epitaxial substrate between said two source regions, said gate terminal having two opposite lateral end portions that respectively overlap said source regions; and
a drain terminal located on said bottom surface of said SiC epitaxial substrate.

2. The semiconductor device as claimed in claim 1, wherein said junction field-effect transistor region (J_{fet}) has a lateral width smaller than a distance between said two well regions so that said junction field-effect transistor region (J_{fet}) does not contact said two well regions.

3. The semiconductor device as claimed in claim 1, wherein
said second lightly doped layer having a doping concentration that is less than a doping concentration of said well regions; and
said heavily doped regions having a doping concentration that is higher than said doping concentration of said well regions.

4. The semiconductor device as claimed in claim 1, wherein said second lightly doped layer of each of said lightly doped regions extends downward from a bottom of said corresponding one of said source regions and juxtaposed to a boundary wall of said heavily doped region.

5. The semiconductor device as claimed in claim 1 further comprising:
an insulating layer having a first insulating layer that covers said top surface of said SiC epitaxial substrate, and a second insulating layer that is located above said first insulating layer, and that covers said gate terminal, said gate terminal being located above said first insulating layer;
a conducting unit having an ohmic contact layer that is electrically connected to said source regions, and a source electrode that is electrically connected to said ohmic contact layer; and
a protection unit made of an insulating material, located above said second insulating layer, and covering said source electrode.

6. A semiconductor device comprising:
a silicon carbide (SiC) epitaxial substrate including a top surface and a bottom surface that is opposite to said top surface;
two well regions spaced apart from each other, each extending downward from said top surface of said SiC epitaxial substrate, and each being doped with a second type dopant;
a junction field-effect transistor region (Jfet) extending downward from said top surface of said SiC epitaxial substrate, located between said two well regions, and doped with a first type dopant, said junction field-effect transistor region (J_{fet}) having a lateral width smaller than a distance between said two well regions so that said junction field-effect transistor (J_{fet}) region does not contact said two well regions;
two source regions respectively extending downward from said top surface of said SiC epitaxial substrate, and located in said two well regions;
a gate terminal located on said top surface of said SiC epitaxial substrate between said two source regions, said gate terminal having two opposite lateral end portions that respectively overlap said source regions; and
a drain terminal located on said bottom surface of said SiC epitaxial substrate.

7. A method for making a semiconductor device comprising:
A) forming a first hard mask unit on a top surface of a silicon carbide epitaxial substrate, the first hard mask unit having a first hard mask layer, a second hard mask layer, and a third hard mask layer that are sequentially stacked upwardly from the top surface of the SiC epitaxial substrate;
B) etching the first hard mask unit via a photolithography process from the third hard mask layer to the first hard mask layer to form two first openings that are spaced apart from each other;
C) doping the SiC epitaxial substrate via ion implantation through the first openings to respectively form two well regions that are doped with a second type dopant, and that are spaced apart from each other;
D) forming a first mask film over the first hard mask unit which is etched to cover the third hard mask layer and the first openings, and then removing the first mask film from the third hard mask layer and a portion of each of the first openings, residual thickness portions of the first mask film being left on boundaries of the first openings to respectively define second openings that each has a size smaller than a size of each of the first openings;
E) performing a first ion implantation through each of the second openings to form a first lightly doped layer, and then performing a second ion implantation through each of the second openings to form a second lightly doped layer that is below the first lightly doped layer and that has a width greater than a width of the first lightly doped layer, the first lightly doped layer being doped with a first type dopant, the second lightly doped layer being doped with a second type dopant;
F) forming a fourth hard mask layer covering the third hard mask layer, the first mask film, and the first hard mask layer exposed from the second openings, forming a second mask film covering the fourth hard mask layer, and then removing the portions of the second mask film corresponding in position to the third hard mask layer and the second openings, residual thickness portions of the second mask film being left on boundaries of the second openings to respectively define third openings that each has a diameter that is smaller than a diameter of each of the second openings;
G) performing an ion implantation through the third openings to form a plurality of source regions extending downwardly from the top surface of each of said source regions, being doped with a first type dopant, and having a doping concentration greater than doping concentrations of the first and second lightly doped layers, each of said source regions having a bottom end that is located at a depth between a depth of a bottom end of the first lightly doped layer and a depth of a bottom end of the second lightly doped layer.

8. The method as claimed in claim 7, further comprising:
H) removing the first to fourth hard mask layers and the first and second mask films, forming a patterned photoresist layer on the top surface of the SiC epitaxial substrate via photolithography that defines a plurality of doping openings that have a width smaller than that of the source regions, performing a heavily doped ion implantation through the doping openings to respectively form two heavily doped regions that are doped with a second type dopant, and then removing the patterned photoresist layer.

9. The method as claimed in claim 7, further comprising:
I) forming a second hard mask unit having a fifth hard mask layer, a sixth hard mask layer, and a seventh hard mask layer that are sequentially stacked upwardly from the top surface of the SiC epitaxial substrate, and then forming an opening that is located between said well regions by etching through the seventh hard mask layer and the sixth hard mask layer to reach the fifth hard mask layer;
J) forming a third mask film covering the second hard mask unit and removing portions of the third mask film corresponding in position to the seventh hard mask layer and the opening of the second hard mask unit, a residual thickness portion of the third mask film being left in the opening of the second hard mask unit to form a fourth opening that has a diameter that is smaller than a minimum distance between said well regions; and
K) performing an ion implantation through the fourth opening to form a junction field-effect transistor region (J_{fet}) that is doped with a first type dopant, that is located between said well regions without contacting said well regions, and then removing the residual portion of the third mask film, and the second hard mask unit.

10. The method of making the semiconductor device as claimed in claim 7, further comprising:
forming an insulating layer having a first insulating layer that covers said top surface of said SiC epitaxial substrate and a second insulating layer that is located above said first insulating layer;
forming a gate terminal that is located above said first insulating layer and covered by said second insulating layer;
forming a conducting unit that is electrically connected to said source regions; and
forming a protection unit made of an insulating material and located above said second insulating layer and said conducting unit.
